(19) United States
(12) Patent Application Publication
(10) Pub. No.: US 2014/0281764 A1
(43) Pub. Date: Sep. 18, 2014

(54) DATA PATH MEMORY TEST

(71) Applicant: TEXAS INSTRUMENTS INCORPORATED, Dallas, TX (US)

(72) Inventors: Susumu Sugie, Urayasu (JP); Seiji Yanagida, Ibaragi-Prefecture (JP)

(73) Assignee: TEXAS INSTRUMENTS INCORPORATED, Dallas, TX (US)

(21) Appl. No.: 13/835,064

(22) Filed: Mar. 15, 2013

(51) Int. Cl. G11C 29/12

(52) U.S. Cl. CPC G11C 29/12
USPC 714/718

(57) ABSTRACT

A system comprises pipeline registers and an integrated circuit comprising a memory array. The integrated circuit is coupled to the pipeline registers, and a data path incorporating the memory array is used to test the integrated circuit.

### BACKGROUND

Integrated circuits (“ICs”) are susceptible to manufacturing defects, called faults, which may cause the ICs to malfunction. Automatic test pattern generation (“ATPG”) is an electronic design automation method and technology used to find a test sequence that, when applied to an IC, enables testers to distinguish between correct circuit behavior and faulty circuit behavior. The generated patterns are used to test ICs after manufacture but before retail sale, and the generated patterns can assist with determining the cause of failure. To determine whether an IC has a fault, the IC is tested using automated test equipment (“ATE”). The number of faults that may be detected by ATE is typically expressed as a percentage of the total number of possible faults and is called the fault coverage of the test. A high value of fault coverage is desirable to avoid the costs associated with delivering defective parts.

ICs with embedded memory elements present problems for ATPG tools because ATPG tools have difficulty modeling the memory elements and fail to produce tests that can initialize and control the outputs of the memory elements.

### SUMMARY

System and methods for testing memory are described herein. In at least some disclosed embodiments, a system includes pipeline registers and an integrated circuit comprising a memory array. The integrated circuit is coupled to the pipeline registers, and a data path incorporating the memory array is used to test the integrated circuit.

In yet other disclosed embodiments, a method includes initializing a memory array in an integrated circuit. The method further includes loading a test for the memory array into at least one pipeline register coupled to the integrated circuit. The method further includes performing a launch-off-capture test on the integrated circuit such that a data path incorporating the memory array is used to test the integrated circuit.

These and other features and advantages will be more clearly understood from the following detailed description taken in conjunction with the accompanying drawings and claims.

### BRIEF DESCRIPTION OF THE DRAWINGS

For a more complete understanding of the present disclosure, reference is now made to the accompanying drawings and detailed description, wherein like reference numerals represent like parts:

FIG. 1 illustrates a memory in an integrated circuit with a data path bypassing the memory array;

FIG. 2 illustrates a memory in an integrated circuit with a data path incorporating the memory array in accordance with at least some illustrative embodiments;

FIG. 3 illustrates programmable built-in self-test logic in accordance with at least some illustrative embodiments; and

FIGS. 4A and 4B illustrate a method and mode states for testing an integrated circuit incorporating a memory array in accordance with at least some illustrative embodiments.

### NOTATION AND NOMENCLATURE

Certain terms are used throughout the following claims and description to refer to particular components. As one skilled in the art will appreciate, different entities may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean an optical, wireless, indirect electrical, or direct electrical connection. Thus, if a first device couples to a second device, that connection may be through an indirect electrical connection via other devices and connections, through a direct optical connection, etc. Additionally, the term “system” refers to a collection of two or more hardware components, and may be used to refer to an electronic device.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one having ordinary skill in the art will understand that the following description has broad application, and the discussion of any embodiment is meant only to be exemplary of that embodiment, and not intended to intimate that the scope of the disclosure, including the claims, is limited to that embodiment.

The effectiveness of ATPG is measured by the amount of faults that are detected. Two categories of faults are stuck-at faults (“SAF”) and transition delay faults (“TDF”). Stuck-at faults occur when a logic element inside the IC that was designed to transition between two logic states (0 and 1) remains in one state due to a chip manufacturing defect. The stuck-at fault model used to test for stuck-at faults is a logical fault model because no delay information is associated with the fault definition, i.e., an error need not be given time to propagate through the circuit. It is also a permanent fault model because the faulty effect is assumed to be permanent, in contrast to intermittent or transient faults, which occur sporadically depending on operating conditions (e.g. temperature, power supply voltage).

A test pattern set with complete stuck-at fault coverage consists of tests to detect every possible stuck-at fault in a circuit. However, complete stuck-at fault coverage does not necessarily guarantee high quality because faults of other kinds—such as bridging faults, opens faults, and transition delay faults—occur. A transition delay fault occurs when a logic element transitions too late or too slow for proper operation due to, for example, excessive net capacitance. Hence, transition delay fault testing detects slow to rise or slow to fall time at a gate input. Special tests check for such difficulties by initiating a transition at the beginning of a path and watching for the response at the end during a defined time window. Specifically, scan-based transition-fault testing techniques are used to test for transition delay faults.

Scan based testing provides a methodology for adding test circuits to a design that allow at least a portion of the state of an IC to be controlled and observed using this added circuitry. Scan testing is performed by enabling the scan circuitry, using the scan circuitry to initialize the IC to at least a partially known state, giving the IC some number of normal functional mode clocks and finally using the scan circuitry to observe at least part of the resulting state. This result is then compared against an expected model.

According to the transition-fault model, there are two types of faults possible: a slow-to-rise fault and a slow-to-fall fault. A slow-to-rise fault means that the effect of any transition from 0 to 1 (or 1 to 0 for slow-to-fall) will not reach a primary output or scan flip-flop within the stipulated time. Two methods to generate test patterns for scan-based testing are the launch-off-capture technique (also called the broadside delay test) and the launch-from-shift technique (also called the skewed load delay test).

To facilitate testing of integrated circuits using automated test equipment (“ATE”), test logic is included in the integrated circuit itself. This test logic is sometimes called programmable built-in self-test logic (“PBIST”). In the launch-from-shift method, the IC is placed in the scan or shift mode, and the test pattern is shifted in from an ATE. The test patterns are shifted through scan chains to initialize, e.g., flip-flop elements to a predetermined state. Next, the IC is placed in capture mode and the response is captured. The output data from the flip-flop elements is captured by other flip-flop elements. Finally, the IC is placed back in scan mode and the response is shifted out and compared with the expected response stored in the ATE. The same clock signal is used during the shift and capture phases, and a scan enable signal is used to control when shifting occurs and when data is captured. The ATE also receives the captured data when it is shifted out and compares the captured data to expected results. This method of testing is called launch-from-shift because the logic under test begins to transition to the state that is captured immediately after the final shift. The last shift clock is used to launch the transition, followed by a quick capture.

In the launch-off-capture method, the test patterns are shifted into the scan chains before launch. The scan-enable signal is toggled, and the circuit enters the functional mode. Next, two clocks with a period corresponding to the functional operating frequency of the circuit are pulsed. The first pulse acts as the launch pulse, and the second pulse captures the effect. Next, the results are scanned out. This method is called launch off capture because the logic under test begins to transition to the final capture state immediately after the first clock pulse of the capture phase.

Referring to FIG. 1, the lowest speed data path in Memory 100 often contains embedded memory elements. Memory array 102 comprises such memory elements. A memory array 102 holds a plurality of logic states and provides a portion of these states in response to an address input. Examples of memory arrays include, but are not limited to, SRAMs (static random access memories), DRAMs (dynamic random access memories), FLASH memories, ROMs (Read Only Memories), etc. In at least one example, and integrated circuit comprises the memory array 102 and/or the memory 100.

A test data path including the memory array 102 presents problems for ATPG tools because ATPG tools have difficulty modeling the memory elements and fail to produce tests that can initialize and control the outputs of the memory elements in an acceptable number of patterns. Dynamic scan chaining provides a mechanism for the test data path 106 to bypass the memory array 102 as a way of reducing test time and the number of test patterns. Scan flip flop 104 is such a bypass mechanism. In at least one embodiment, the bypass mechanisms are multiplexers (“muxes”) built into the scan chains at various points in a way that permits bypassing memory arrays 102. The test data path 106 in FIG. 1 incorporates the at least one scan flip flop 104, mux 108, and at least one capture flip flop 110. ATE is not shown. The arrows represent the direction that test data travels through the Memory 100.

The Memory 100 is in ATPG mode when the ATPGM pin 112 is high. While in ATPG mode, the memory array 102 is disabled and input data from outside memory array 102 goes to scan flip flop 104, which indicates bypass mode. When the ATPGM pin is low, the scan flip flop 104 is disabled and Mux 108 selects signals from Memory Array 102. This ATPGM 112 can be controlled by test mode controller 130. Referring to FIG. 2, in at least one embodiment, the ATPGM pin 112 is set to low during ATPG mode in order to enable the memory array 102. Propagating, or pipelining, the data path requires that values passed from one scan chain to the next are placed in registers, called pipeline registers 116. The pipeline registers 116 also carry data for the programmable built-in self-test logic 118. During ATPG mode, the pipeline registers 116 control address, enable, and read/write signals for memory array 102. This control can be achieved by loading proper data for memory mode setting by scan shift because the pipeline registers are part of the scan registers. Preferably, setting the pin 112 to low does not disrupt ATPG mode as the pin 112 is controlled apart from ATPG mode.

The pipeline registers 116 are used to activate the memory array 102 during ATPG mode. Because the memory array 102 is enabled, the test data path 114 travels through the memory array 102 instead of bypassing the memory array 102 via the scan flip flop 104, which is disabled. As such, an at-speed test of the Memory 100 can be performed because the test data path 114 incorporates the memory array 102. In an embodiment, after the initialization of the memory 100, the ATPGM pin 112 is set to high and memory access control signals such as the address signal are stored into the pipeline registers 116. When memory 100 exits from the ATPG mode, the ATPGM pin 112 is set low and the pipeline registers 116 have access to memory 100 by using the stored memory access control signals.

Preferably, PBIST 118 initializes the memory array 102 for test. Referring to FIG. 3, in at least one embodiment, PBIST comprises an algorithmic address generator 120, an algorithmic data generator 122, a program storage unit 124, and loop control mechanisms 126. The address generator 120 is responsible for generating the memory address where the next data are read from or written into. Correct address generation is preferably used when the physical mapping of a memory array 102 is different from its logical mapping. In order to achieve the required test coverage, the address generator 120 generates addresses in different fashions in order to accommodate different kinds of addressing flows such as March-C, Galloping patterns, Address Complements, Fast X, and Fast Y.

The data generator 122 plays a very similar role to the address generator 120, but in reverse. In order to get the inverse data for each physically adjacent cell, the logical-to-physical mapping of the memory array 102 is used.

The loop control system 126 is the sequencing logic in PBIST 118 that allows testing of the entire memory array 102 using only a few program steps. Without the loop control system 126, test programs of thousands of lines need to be written in order to test the memory array 102. Also, PBIST 118 can be used for test during burn-in (“TDBI”) where the Memory 100 is tested while manufactured. The test pattern includes the types of operations to be performed (e.g., memory read, memory write), the types of address generation modes, the data to be written into and read out from the memory array 102, and the types of looping schemes. PBIST 118 circumvents the need to develop and buy increasingly sophisticated and expensive testers, and can be used for large memory ICs that have high pin counts and operate at high frequencies. The program storage unit 124 stores the instructions used to test the Memory 100 and memory array 102.

FIGS. 4A and 4B illustrate a method 400 beginning at 402 and ending at 410. The mode states are described in the table of FIG. 4B. At 404, the memory array is initialized via the PBIST. Contents of memory array are written such that a ‘0’ or ‘1’ will output from the memory. As such, the controller and memory are in PBIST mode, while the pipeline register is in test mode. An “x” in the table denotes that it is unimportant which mode the corresponding element is in during the corresponding step. At 406, a value is loaded into the pipeline registers by scan shift to set the memory into read mode. At this time, a read operation of the memory array can be prepared comprising a launch operation for the launch-off-capture test. In addition, to protect the contents of memory, ATPGM is set to high and the memory is separated from the peripheral circuits, such as the pipeline registers. As such, the pipeline register and any other logic in the path are in ATPG scan shift mode. At 408, the launch-off-capture test is performed such that a data path (the test data path) incorporates the memory array and data from the pipeline registers is shifted into the memory array. As such, the memory is in read mode while the pipeline register and any other logic in the path are in ATPG launch-off-capture mode.

Other conditions and combinations of conditions will become apparent to those skilled in the art, including the combination of the conditions described above, and all such conditions and combinations are within the scope of the present disclosure. Additionally, audio or visual alerts may be triggered upon successful completion of any action described herein, upon unsuccessful actions described herein, and upon errors.

The above disclosure is meant to be illustrative of the principles and various embodiment of the present invention. Numerous variations and modifications will become apparent to those skilled in the art once the above disclosure is fully appreciated. Also, the order of the actions shown in FIG. 4 can be varied from order shown, and two or more of the actions may be performed concurrently. It is intended that the following claims be interpreted to embrace all variations and modifications.

I claim:

1. A system, comprising:
pipeline registers; and an integrated circuit comprising a memory array, the integrated circuit coupled to the pipeline registers;
wherein a data path incorporating the memory array is used to test the integrated circuit.

2. The system of claim 1, wherein the integrated circuit comprises an automatic test pattern generation (“ATPG”) pin; wherein the integrated circuit is operable in ATPG mode when the pin is high.

3. The system of claim 1, wherein the data path does not incorporate a scan flip flop used to bypass the memory array.

4. The system of claim 2, wherein, during ATPG mode, the pin is set low to disable a scan flip flop used to bypass the memory array.

5. The system of claim 1, wherein the memory array is tested is at-speed.

6. The system of claim 2, wherein the pipeline registers are used to activate the memory array during ATPG mode.

7. The system of claim 1, wherein the integrated circuit comprises programmable built-in self-test logic; and wherein the programmable built-in self-test logic initializes the memory array for test.

8. A method, comprising:
initializing a memory array in an integrated circuit;
loading a test for the memory array into at least one pipeline register coupled to the integrated circuit;
performing a launch-off-capture test on the integrated circuit such that a data path incorporating the memory array is used to test the integrated circuit.

9. The method of claim 8, wherein the memory array is initialized via programmable built-in self-test logic.

10. The method of claim 8, wherein performing the launch-off-capture test comprises shifting data into the memory array from the pipeline registers.

11. The method of claim 8, further comprising disabling a scan flip flop used to bypass the memory array.

12. The method of claim 8, further comprising setting an automatic test pattern generation pin to low during ATPG mode.

13. The method of claim 8, wherein the test is at-speed.

14. The method of claim 8, further comprising using the pipeline registers to activate the memory during ATPG mode.

15. The method of claim 11, wherein disabling the scan flip flop comprises disabling the scan flip flop such that the data path does not incorporate the scan flip flop.
